(19) United States
(12) Patent Application Publication
(10) Pub. No.: US 2025/0019241 A1
(43) Pub. Date: Jan. 16, 2025

(54) MICROWAVE APPARATUS AND METHOD FOR PRODUCTION OF CARBON MATERIALS

(71) Applicant: 6K Inc., North Andover, MA (US)

(72) Inventors: Jared Majcher, Portsmouth, NH (US); Makhlouf Redjdal, Melrose, MA (US); Judith Lee, Billerica, MA (US); Vikram Singh, Andover, MA (US)

(21) Appl. No.: 18/766,324

(22) Filed: Jul. 8, 2024

Related U.S. Application Data
(60) Provisional application No. 63/512,868, filed on Jul. 10, 2023.

(51) Int. Cl. C01B 32/16; C01B 32/186; C23C 16/27; C23C 16/511

(52) U.S. Cl. CPC C01B 32/16; C01B 32/186; C23C 16/274; C23C 16/511; C01B 2202/06

(57) ABSTRACT

Embodiments disclosed herein relate to a systems, methods, and apparatus for the production of solid carbon materials and carbon containing gasses. The embodiments disclosed herein may facilitate the conversion of carbon-containing gases into carbon monoxide gas and/or solid carbon materials, such as, for example graphene, carbon nanocages, and carbon nanotubes. The process is cost efficient, energy efficient, and environmentally friendly with the ability to use or recycle carbon-containing gasses to produce solid carbon products.

### INCORPORATION BY REFERENCE TO ANY PRIORITY APPLICATIONS

This application claims priority to U.S. Patent Application 63/512,868, which was filed on Jul. 10, 2023, the entire disclosure of which is incorporated by reference herein for any and all purposes.

### BACKGROUND

### Field

The present disclosure is generally directed to the production of carbon containing materials and methods of production thereof.

### Description

Carbon dioxide (CO₂) is a greenhouse gas, and many methods are being devised to remove carbon dioxide from the atmosphere in order to mitigate the warming effects of CO₂ on a global scale. Many such methods involve the storage and compression of carbon dioxide gas in underground caverns or the conversion of carbon dioxide to solid, carbon containing waste materials that may be safely stored.

Carbon containing products with an ordered structure have been desirable for their unique mechanical and electrical properties. For example, graphene has been shown as an exceptionally superior electrical conductor with a minimal resistance to electrical flow. Furthermore, graphene is mechanically durable with one of the highest strength to weight ratios ever recorded, is generally impermeable to gasses, and displays high mobility of charge carriers. Carbon nanotubes (CNTs) and multi-walled carbon nanotubes (MWCNTs) are also highly desirable for their electrical conductivity, exceptional tensile strength, unique properties, and high thermal conductivity.

Carbon nanotubes are generally produced via chemical vapor deposition (CVD), arc discharge, laser ablation, and high-pressure carbon monoxide disproportionation (HiPCO). However, many of these processes require a vacuum or a tightly regulated gaseous atmosphere. CVD is the most common method for the production of carbon nanotubes. However, CVD is a batch process in which consistency and repeatability is difficult. HiPCO presents an alternative synthesis route via a continuous growth process, but HiPCO requires reactors that operate at high temperatures of 900-1100° C. and high pressures of ˜30-50 bar.

Graphene has been produced in a variety of processes, including CVD, graphite oxide reduction, solvent interface trapping, supersonic spraying, and hydrothermal self-assembly. However, these processes can take hours or days to produce graphene with the desired quality and purity.

Thus, there is a need to produce ordered carbon structures in processes that are more efficient and economical than known processes.

### SUMMARY

For purposes of this summary, certain aspects, advantages, and novel features of the invention are described herein. It is to be understood that not all such advantages necessarily may be achieved in accordance with any particular embodiment of the invention. Thus, for example, those skilled in the art will recognize that the invention may be embodied or carried out in a manner that achieves one advantage or group of advantages as taught herein without necessarily achieving other advantages as may be taught or suggested herein.

In some aspects, the techniques described herein relate to a method for producing a solid carbon material using a microwave generated plasma, the method including: propagating microwaves through a microwave plasma apparatus, the microwaves generated using a microwave generator; injecting a plasma gas including carbon into the microwave plasma apparatus; and generating the microwave generated plasma by contacting the plasma gas with the microwaves, wherein contacting the plasma gas with the microwaves pyrolyzes the plasma gas to produce oxygen (O2) gas and a carbon-containing gas; and depositing the carbon-containing gas on a substrate to form the solid carbon material.

In some aspects, the techniques described herein relate to a method, wherein the solid carbon material includes an array of repeating carbon atoms.

In some aspects, the techniques described herein relate to a method, wherein at least one portion of the substrate includes a catalyzing transition metal.

In some aspects, the techniques described herein relate to a method, wherein the solid carbon material includes a crystalline carbon material.

In some aspects, the techniques described herein relate to a method, wherein the crystalline carbon material includes a carbon nanotube (CNT) or multi-walled carbon nanotube (MWCNT).

In some aspects, the techniques described herein relate to a method, wherein the solid carbon material includes an array of sp² hybridized carbon atoms.

In some aspects, the techniques described herein relate to a method, wherein the solid carbon material includes a graphene sheet or carbon nanocages.

In some aspects, the techniques described herein relate to a method, wherein at least one surface of the substrate includes a catalyst.

In some aspects, the techniques described herein relate to a method, wherein the catalyst facilitates growth of the solid carbon material in a repeating carbon structure including substantially pure carbon.

In some aspects, the techniques described herein relate to a method, wherein the catalyst includes particles having a diameter of about 1 nm to about 10 nm.

In some aspects, the techniques described herein relate to a method, wherein contacting the plasma gas with the microwaves pyrolyzes the plasma gas to further produce a carbon-containing gas.

In some aspects, the techniques described herein relate to a method, further including recycling the carbon-containing gas and injecting the recycled carbon-containing gas into the microwave plasma apparatus.

In some aspects, the techniques described herein relate to a method, wherein the microwave plasma apparatus includes one or more walls lined or coated with a material that prevents deposition of the solid carbon material on the one or more walls.

In some aspects, the techniques described herein relate to a method, wherein the microwave plasma apparatus is maintained at atmospheric pressure during the method.

In some aspects, the techniques described herein relate to a method, further including injecting an enabling gas into the microwave plasma apparatus while injecting the plasma gas into the microwave plasma apparatus.

In some aspects, the techniques described herein relate to a microwave plasma apparatus for generating a solid carbon material using a microwave generated plasma, the apparatus including: a microwave waveguide for propagating microwaves generated using a microwave generator; one or more gas ports for injecting a plasma gas, the one or more gas ports in communication with the microwave waveguide; a reaction chamber with one or more chamber walls, the reaction chamber in communication with the microwave waveguide and the one or more gas ports, the reaction chamber including a heating region and a deposition region, and the one or more chamber walls including a lining or coating including a material that prevents crystal growth on the one or more chamber walls; a substrate holder located in the deposition region of the reaction chamber, the substrate holder configured to house a substrate for depositing the solid carbon material thereon; and a gas separator in communication with the reaction chamber, the gas separator configured to separate one or more gases generated in the heating region and/or the deposition region of the reaction chamber.

In some aspects, the techniques described herein relate to an apparatus, wherein the substrate holder is substantially perpendicular to the one or more chamber walls.

In some aspects, the techniques described herein relate to an apparatus, wherein the substrate holder is substantially parallel to the one or more chamber walls.

In some aspects, the techniques described herein relate to an apparatus, wherein the substrate is configured to unroll and expose a catalyzing material.

In some aspects, the techniques described herein relate to an apparatus, wherein one or more portions of the substrate holder are removable and replaceable.

In some aspects, the techniques described herein relate to a solid carbon material synthesized according to a method including: propagating microwaves through a microwave plasma apparatus, the microwaves generated using a microwave generator; injecting a plasma gas including carbon into the microwave plasma apparatus; generating a microwave generated plasma by contacting the plasma gas with the microwaves, wherein contacting the plasma gas with the microwaves pyrolyzes the plasma gas to produce oxygen (O₂) gas and a carbon-containing gas; and depositing the carbon-containing gas on a substrate to form the solid carbon material.

In some aspects, the techniques described herein relate to a solid carbon material synthesized according to a method including: propagating microwaves through a microwave plasma apparatus, the microwaves generated using a microwave generator; injecting a plasma gas including carbon into the microwave plasma apparatus; generating a microwave generated plasma by contacting the plasma gas with the microwaves, wherein contacting the plasma gas with the microwaves pyrolyzes the plasma gas to produce oxygen (O₂) gas and a carbon-containing gas; and depositing the carbon-containing gas on a substrate to form the solid carbon material.

In some aspects, the techniques described herein relate to a method for producing carbon monoxide using a microwave generated plasma, the method including: propagating microwaves through a microwave plasma apparatus, the microwaves generated using a microwave generator; injecting a plasma gas including carbon into the microwave plasma apparatus; generating the microwave generated plasma by contacting the plasma gas with the microwaves, wherein contacting the plasma gas with the microwaves pyrolyzes the plasma gas to produce carbon monoxide (CO) gas; and removing the carbon monoxide gas from the microwave plasma apparatus.

In some aspects, the techniques described herein relate to a method, wherein the removing the carbon monoxide gas from the microwave plasma apparatus includes separating the carbon monoxide gas from other gaseous byproducts to purify the carbon monoxide gas.

In some aspects, the techniques described herein relate to a method, wherein the gaseous byproduct is oxygen gas (O₂).

In some aspects, the techniques described herein relate to a method, wherein the plasma gas including carbon is carbon dioxide (CO₂).

In some aspects, the techniques described herein relate to a method, wherein the method further includes purifying oxygen gas (O₂) as a byproduct of the method for producing carbon monoxide.

In some aspects, the techniques described herein relate to a method, additionally including depositing a solid carbon material on a substrate within the microwave plasma apparatus.

### BRIEF DESCRIPTION OF THE DRAWINGS

The drawings are provided to illustrate example embodiments and are not intended to limit the scope of the disclosure. A better understanding of the systems and methods described herein will be appreciated upon reference to the following description in conjunction with the accompanying drawings, wherein:

FIG. 1 illustrates a diagram of an example swirl flow microwave plasma system according to some embodiments herein.

FIG. 2 illustrates an example microwave plasma apparatus with a deposition module according to some embodiments herein.

FIG. 3A illustrates an example microwave plasma apparatus with a continuous processing module according to some embodiments herein.

FIG. 3B illustrates an example microwave plasma apparatus with an inverted configuration according to some embodiments herein.

FIG. 4 illustrates an example microwave plasma torch that can be used in the production of materials according to some embodiments herein.

FIGS. 5A-B illustrate an exemplary microwave plasma torch that includes a side feeding hopper, thus allowing for downstream feeding, according to some embodiments herein.

FIG. 6 illustrates an exemplary microwave plasma torch that can be used in the production of solid carbon materials according to some embodiments.

FIG. 7 shows images of nanocages produced according to some embodiments herein.

### DETAILED DESCRIPTION

Although certain preferred embodiments and examples are disclosed below, inventive subject matter extends beyond the specifically disclosed embodiments to other alternative embodiments and/or uses and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied as integrated components or as separate components. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein.

Certain exemplary embodiments will now be described to provide an overall understanding of the principles of the structure, function, manufacture, and use of the devices and methods disclosed herein. One or more examples of these embodiments are illustrated in the accompanying drawings. Those skilled in the art will understand that the devices and methods specifically described herein and illustrated in the accompanying drawings are non-limiting exemplary embodiments and that the scope of the invention is defined solely by the claims. The features illustrated or described in connection with one exemplary embodiment may be combined with the features of other embodiments. Such modifications and variations are intended to be included within the scope of the present technology.

In some embodiments, microwave plasma processes to perform heating and/or pyrolyzing of carbon-containing gases and produce solid carbon-containing materials, are provided herein. As used herein, carbon-containing gas may comprise any gas that has a composition comprising at least one carbon atom. Examples of carbon-containing gas include, but are not limited to, carbon dioxide (CO₂), methane (CH₄), carbon monoxide (CO), ethylene (C₂H₄), propane (C₃H₈), butane (C₄H₁₀), acetylene (C₂H₂), propylene (C₃H₆), isobutane (C₄H₁₀), benzene (C₆H₆), ethane (C₂H₆), formaldehyde (CH₂O), dimethyl ether (C₂H₆O), ethanol (C₂H₅OH), methanol (CH₃OH), ethyne (C₂H₂), methyl mercaptan (CH₃SH), ethyl mercaptan (C₂H₅SH), carbon disulfide (CS₂), phosgene (COCl₂), acetaldehyde (C₂H₄O), acetic acid (C₂H₄O₂), acetone (C₃H₆O), acetonitrile (CH₃CN), carbon tetrachloride (CCl₄), dichloromethane (CH₂Cl₂), toluene (C₇H₈), xylene (C₈H₁₀), ethylbenzene (C₈H₁₀), styrene (C₈H₈), phenol (C₆H₆O), propionic acid (C₃H₆O₂), acrylonitrile (C₃H₃N), formic acid (CH₂O₂), propionaldehyde (C₃H₆O), dimethylamine (C₂H₇N), pyridine (C₅H₅N), and furan (C₄H₄O), among others. As used herein, solid carbon-containing materials generally refer to, but are not limited, to carbon allotropes such as graphite, graphene, amorphous carbon, carbon black, carbon nanotubes, multi-walled carbon nanotubes, carbon nanocages, fullerenes, carbon nanohorns, carbon nanofoam, lonsdaleite, glassy carbon, diamond, diamond nanorods, carbon fibers, carbon onions, carbyne, Q-carbon, and carbon nanoplatelets.

In some embodiments, although carbon nanotubes (CNTs) and multi-walled carbon nanotubes (MWCNTs) may be formed during carbon formation, a percentage of carbon may be converted to graphene nanoplatelets. Advantageously, microwave plasma processes such as those described herein may be performed under atmospheric conditions and synthesize a product with high purity and reproducibility. In some embodiments, microwave plasma technology provides a stable and consistent plasma. In some embodiments, additional hot zone technologies may provide controlled heating of carbon containing gases to produce oxygen and structured carbon. Thus, methods for producing carbon structures and oxygen byproducts are presented herein.

The solid carbon materials produced according to this process may be optimized to be used for reinforced composites, flexible electronics, transparent conductors, biological, optical or chemical sensors, thermal interfaces, advanced composites, 3D energy storage and membranes, lightweight CNT conductors, or quantum wires.

Some embodiments herein relate to the use of microwave plasma processing to produce solid carbon-containing materials in bulk. A microwave plasma at atmospheric pressure is generally considered a thermal plasma, i.e., electrons and ions have energy at the same level due to high collision frequency. However, in some embodiments, the degree of ionization may not be exceedingly high, only about 10% of gas particles becoming ionized. While the ion energies in microwave plasmas are lower than those of higher potential direct-current (DC) arc systems, the electron energies are quite high. In some embodiments, this property allows for microwave plasma to form radicals which can be used to enhance or even initiate certain chemical steps which would otherwise not occur at certain pressures and temperatures. The chemical species present in radio frequency (RF) plasma at higher powers compared to that of lower power microwave plasma show that a higher intensity and degree of radicals are present in the microwave plasma over the RF.

Plasma torches generate and provide high temperature directed flows of plasma for a variety of purposes. The two main types of plasma torches are induction plasma torches and microwave plasma torches. Generally, inductive plasmas suffer from plasma non-uniformity. This non-uniformity leads to limitations on the ability of inductive plasmas to process certain materials. Furthermore, significant differences exist between the microwave plasma apparatuses and other plasma generation torches, such as induction plasma. For example, microwave plasma is hotter on the interior of the plasma plume, while induction is hotter on the outside of the plumes. In particular, the outer region of an induction plasma can reach about 10,000 K while the inside processing region may only reach about 1,000 K. This large temperature difference leads to material processing and feeding problems. Furthermore, induction plasma apparatuses are unable to process feedstocks at low enough temperatures to avoid melting of certain feed materials without extinguishing the plasma.

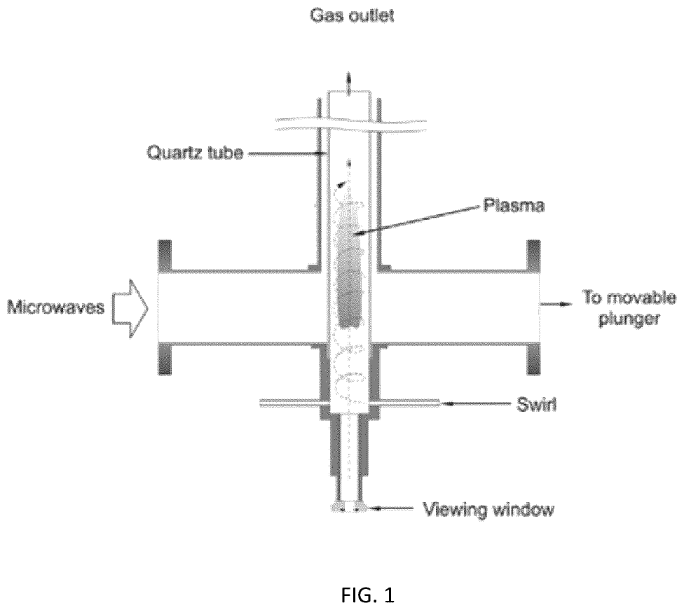

Unlike other plasma systems driven by high voltage potentials (e.g., DC arc), in some embodiments, microwave plasmas are primarily driven by the avalanche effect with an initial seed of free electrons required to begin the plasma. In some embodiments, joule heating of the gas follows as the ionized gases couple the microwave energy and continue to heat the surrounding gases. An example microwave plasma torch setup according to some embodiment is shown in FIG. 1. In some embodiments, the plasma gas is injected into a quartz tube, which directs the plasma gas toward a reaction chamber. Prior to entering the reaction chamber, the plasma gas is exposed to a microwave, which propagates to the quartz tube through a waveguide where it is applied to the plasma gas. The ionized gas is then exhausted into the reaction chamber where mixing and recombination of the ionized species may occur. In some embodiments, one or more swirl gases may be applied to protect the apparatus from the ionized plasma gas and/or to direct the plasma gas to the reaction chamber.

In some embodiments, two main methods of carbon-containing gas breakdown may occur through application of microwave plasma: ionization and pyrolysis. Ionization of a gas refers to the process of converting neutral gas atoms or molecules into ions by adding or removing electrons. This process occurs when the gas particles gain or lose electrons, resulting in the formation of positively charged ions (cations) and negatively charged ions (anions). In some embodiments, ionization of a carbon-containing gas occurs when enough energy is coupled into a gas molecule to raise an electron out of the gas molecule's orbital. In the case of carbon dioxide, there are many ionization states which can occur. For example, an electron may be stripped, creating CO₂⁺. In some embodiments, for example, an electron may be stripped, creating a double ionization of CO₂²⁺. Ionization may proceed further and with pyrolysis and decomposition to CO⁺ and separation of all C—O bonds to create C⁺, O⁺, and O₂⁺.

Pyrolysis of carbon-containing gas may refer to the thermal decomposition of the gas into its constituent elements, such as, for example, carbon (C) and oxygen (O₂) for CO₂. In some embodiments, pyrolysis occurs at high temperatures of 600 to 1200 degrees Celsius and involves an endothermic process that requires a significant amount of energy input. During the pyrolysis of CO₂, the carbon dioxide molecule undergoes a dissociation reaction, breaking apart into carbon and oxygen. The reaction can be generally represented by the following equation excluding intermediaries: CO₂ (g)→C(s)+O₂ (g). The overall reaction proceeds with the creation of carbon monoxide such that 2CO₂ (g)→2CO (g)+O₂ (g) followed by the two carbon monoxide molecules being converted to O₂ (g) and two carbon atoms being incorporated into the solid carbon structure, which is generally represented by 2CO (g)→2C(s)+O₂. The process involves the breaking of the strong carbon-oxygen bonds present in carbon dioxide, resulting in the formation of the elemental components. In some embodiments, a catalyst may be utilized to facilitate pyrolysis. In some embodiments, CO (g) may be injected into the microwave plasma apparatus instead of CO₂ (g) in order to facilitate the growth of certain solid carbon containing products, such as carbon nanocages.

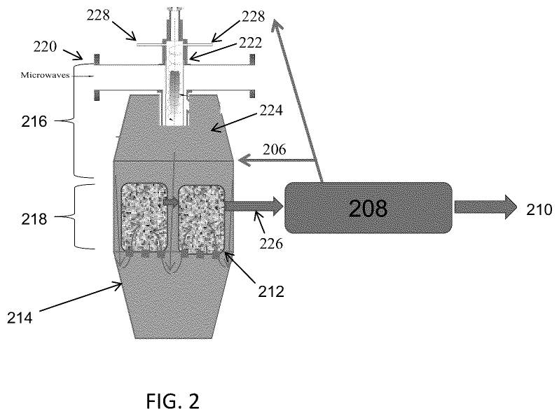

In some embodiments the process may be configured to produce carbon monoxide gas. For example, the conditions for the microwave plasma apparatus may be configured to proceed via the reaction 2CO₂ (g)→2CO (g)+O₂ (g). This reaction pathway may proceed with little or no conversion to solid carbon, C(s). In some embodiments the microwave plasma apparatus may be configured to produce solid carbon, such as carbon nanotubes, nanocages, or graphene, and also carbon monoxide gas (CO) as products. In some embodiments the carbon monoxide may be removed from the reaction chamber and separated from other gaseous byproducts, such as O₂ (g). In some embodiments some of the CO gas may be recycled back into the microwave plasma apparatus. FIG. 2 illustrates a microwave plasma apparatus 200 for heating and deposition of carbon-containing gases. In some embodiments, the microwave plasma apparatus 200 may operate under atmospheric pressure. In some embodiments, the microwave plasma apparatus 200 may comprise one or more injection ports 228 for the injection of a gas, such as a carbon-containing gas such as substantially enriched carbon dioxide or substantially pure carbon dioxide, or a mixture of carbon-containing gasses. In some embodiments, the one or more injection ports 228 may be used to inject a mixture of carbon-containing gases, such as carbon dioxide, carbon monoxide, or other carbon-containing gasses. Various gasses or gas mixtures that may be provided in the one or more injections ports 228, including carbon-containing gases, oxygen, ozone (O₃), water vapor, or inert gasses such as nitrogen (N₂), helium (He), Hydrogen (H₂), or Argon. In some embodiments, enabling gasses are provided in the one or more injection ports 228 that enable and/or facilitate the synthesis of crystalline carbon materials. The additional injection port 202 may be used to recycle pyrolyzed gasses back into the plasma of the apparatus. Recycled gasses may include carbon monoxide, carbon dioxide, oxygen, other carbon-containing gasses, or a mixture of these gasses.

As mentioned previously, the injection port 228 may be used to inject carbon-containing gases into the plasma of the apparatus. Advantageously, in some embodiments, carbon-containing gases provide the carbon atoms that are incorporated into solid carbon materials that are synthesized according to embodiments disclosed herein. In some embodiments, this is cost effective, as may carbon-containing gases, such as carbon dioxide, are greenhouse gases and sequestration and reduction of carbon-containing gases in the atmosphere is highly desirable. As will be explained further herein, in some embodiments, the byproduct of the methods disclosed herein is primarily oxygen.

In some embodiments, the injection of one or more carbon containing gasses through injection port 228 may create a swirl, and the swirl may be aided through the introduction of additional gasses through one or more other injection ports 228.

In some embodiments, after introduction of the carbon-containing gases to the tube 222 or into a liner of the tube 222, microwaves may be propagated through waveguide 220. In some embodiments, the microwaves energize and ionize the carbon-containing gases. In some embodiments, in processing region 216, heating and decomposition of the carbon-containing gases may occur. As discussed above, carbon-containing gases may be ionized and/or heated in processing region 216 to create lower molecular weight radicals that are highly reactive. In some embodiments, the pyrolyzed atoms or molecules proceed through the apparatus to a reaction chamber 224. In some embodiments, in the deposition region 218 of the reaction chamber 224, the atoms or molecules processed in processing region 216 may be deposited as a solid carbon material. In some embodiments, in the deposition region 218, the growth of solid carbon structures may be facilitated by a substrate 212 or module. Although FIG. 2 depicts a substrate or module that is substantially horizontal, in some embodiments, the substrate may be oriented in any direction, such as a vertical or angled direction relative to the flow of the gases through the reaction chamber 224. In some embodiments, the substrate 212 or module may extend to the outer edges (i.e., the entire width) of the chamber 224 from the center of the reaction chamber 224, or the substrate may extend only partially the width of the reaction chamber 224. In some embodiments, the reaction chamber 224 may comprise a substantially cylindrical shape, and the substrate 212 or module may comprise a circular deposition region with a diameter that substantially extends to the inner diameter of the reaction chamber 224. In some embodiments, a horizontal substrate 212 or module allows for continued growth of CNTs or MWCNT's on the micro or macro scale. In some embodiments the substrate 212 may be removed or dispensed with in order to facilitate the production of CO (g) as the product of the pyrolysis reaction, producing little to no solid carbon in the process. In some embodiments the reactants and the products are gaseous, such that the pyrolysis reaction is a gaseous to gaseous reaction. Advantageously, this may reduce unwanted deposition of materials and reduce the interaction of products with the walls of the microwave plasma apparatus.

Substrate or module 212 may be porous, such that currents and countercurrents of gasses may penetrate the substrate 212 or module. However, in some embodiments, the substrate may be solid or substantially solid. In some embodiments, the substrate or module may comprise a fluidized bed or a semi-fluidized bed that fluidizes the solid carbon particles on top of the substrate 212. In some embodiments, the porous nature of the substrate or module may facilitate the mixing of gasses in the chamber 224 to increase the homogeneity of the reactants in the chamber 224.

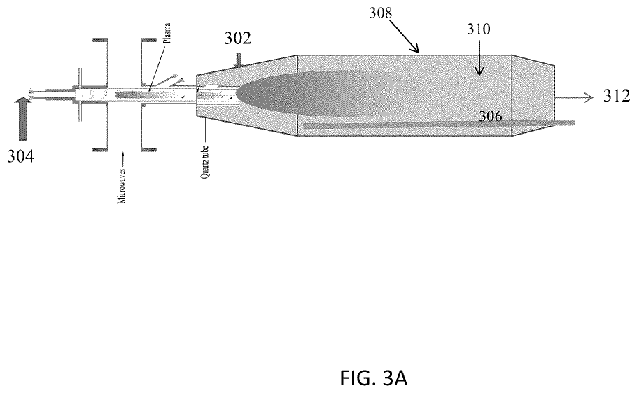

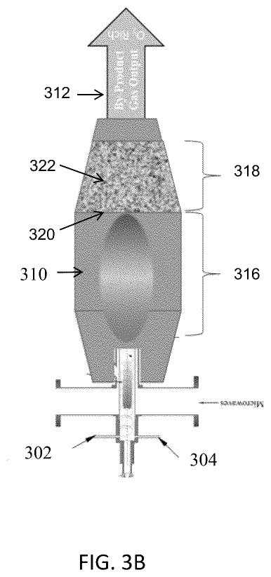

In some embodiments, substrate 212 or module may be provided in sections such that various portions of the substrate 212 may be removed separately from other portions of the substrate 212. In some embodiments, substrate 212 or module may be provided as a continuous sheet that is entirely removed and replaced. Thus, the synthesis of solid carbon materials may occur in a batchwise process, in a semi-continuous process, or in a continuous process. In some embodiments the substrate 212 or module may be provided with or adjacent to micro or nanometer particles for the growth of solid carbon materials. In some embodiments the catalyzing substrate is the micro or nanometer particles and 212 functions as a substrate holder, which is discussed more in FIG. 3B. In some embodiments where the catalyzing substrate is provided horizontally the carbon nanotubes may be deposited or grown in an extended vertical direction. For example, the CNTs may be deposited such that they have a cylinder length of at least about 1 micron, at least about 10 microns, at least about 20 microns, at least about 50 microns, at least about 100 microns, at least about 200 microns, at least about 400 microns, at least about 800 microns, at least about 1 mm or at least about 2 mm.

Advantageously, in some embodiments, the substrate or module may be provided with a catalyzing composition to facilitate the growth or synthesis of carbon-containing particles on or near the substrate's surface. In various embodiments, only portions of the substrate or module may comprise catalyzing sections or the entire substrate or module may contain a catalyzing surface. In various embodiments, the substrate may comprise transition metals of the periodic table, such as metals having filled or partially filled d-orbitals of the periodic table. In some embodiments the catalyzing material may be W, Ta, Fe, Mo, Co, Cu, Cr, Ru, Co, Ag, Pt, Pd, Au, Ni, or alloys and mixtures thereof. In some embodiments the catalyzing substrate may be an organic layer doped with transition metals. In some embodiments, the substrate is comprised entirely of a single transition metal catalyzing element. In other embodiments the substrate may have a bimetallic or trimetallic composition. In other embodiments, the substrate may comprise a mixture or alloy of metallic elements. In some embodiments, various portions of the substrate may be apportioned or rasterized to facilitate growth or synthesis of carbon-containing molecules in certain locations. In some embodiments the catalyzing material may be a single element to facilitate the growth of single walled CNTs or more than one catalyzing element may be provided the facilitate the growth of MWCNTs. In some embodiments the catalyzing material is sized to facilitate the growth of single walled CNTs, MWCNTs, or graphene. In some embodiments the catalyzing material may be particles having diameters of about 1 nm to about 10 nm, or about 1 nm to about 5 nm.

In some embodiments, the deposition region 218 may be optimized for the growth carbon-containing molecules, such as ordered or crystallized carbon-containing molecules. In some embodiments, the crystallized or ordered carbon-containing molecules are substantially or entirely composed of carbon. For example, the carbon-containing molecules may be composed of more than 99.9% carbon. In some embodiments, the carbon-containing molecules are only composed of carbon molecules. In some embodiments, exemplary carbon-containing molecules include molecules that contain carbon arrays or carbon lattices. For example, graphene is an exemplary carbon containing molecule comprised of carbon atoms in a single sheet. In graphene, the carbon atoms are connected in a two-dimensional manner and are sp² hybridized. Another exemplary carbon containing molecule is a carbon nanotube (CNT), which comprises a cylinder of carbon atoms that are connected in a hollow tube or a multi-walled carbon nanotube (MWCNT), which is two or more cylinders of carbon atoms where one cylinder is nested within the other cylinder. In carbon nanotubes, the carbon atoms are sp² hybridized.

Additional carbon containing molecules may be synthesized according to the methods herein. For example, the catalyzing surface of the plasma chamber 224 may be optimized for the growth of fullerenes or for the growth of pure sp³ hybridized carbon lattices, such as in a diamond. In some embodiments, the catalytic substrate may be optimized for growth of the desired class of solid carbon molecules, such as nanotubes, carbon nanocages, multi-walled carbon nanotubes, graphene, and fullerenes, among others.

In some embodiments, the system and substrate may be optimized to deposit carbon atoms in a regular, repeating order. In some embodiments, the deposited molecules may be exclusively composed of carbon atoms. For example, the deposited molecules may comprise a purity of at least 90%, 91%, 92%, 93%, 94%, 95%, 96%, 97%, 98%, 99%, 99.9%, 99.99%, 99.999%, or any value between the aforementioned values. In some embodiments, this level of purity is possible due to the reaction components being exclusively carbon and oxygen, such as from carbon dioxide and/or carbon monoxide. In other embodiments, other elements or impurities may be incorporated into the carbon-containing products.

In some embodiments the system may be configured to convert carbon-containing gasses to substantially pure carbon monoxide and oxygen gas. For example, the gaseous byproducts may have a purity of at least 90%, 91%, 92%, 93%, 94%, 95%, 96%, 97%, 98%, 99%, 99.9%, 99.99%, 99.999%, or any value between the aforementioned values. In some embodiments, this level of purity is possible due to the reaction components being exclusively carbon and oxygen, such as from carbon dioxide and/or carbon monoxide.

Some embodiments herein may refer to “ordered” carbon products or “crystalline” carbon products. These terms generally refer to the ordered carbon sheets of graphene, carbon nanotubes, or multi-walled carbon nanotubes, in which one carbon atom is connected to three other carbon atoms, and so on, in a continuous array. In some embodiments, these terms may refer to other highly ordered structures, such as diamonds or fullerenes.

In various embodiments, the production of ordered carbon products may be performed in a single stage. In this single stage synthesis carbon nanotubes, multi-walled carbon nanotubes, carbon nanocages, or graphene sheets may be produced without significant intermediaries. For example, carbon atoms from carbon dioxide may be directly deposited or incorporated atom-by-atom, layer-by-layer, or section by section into the sp² hybridized structure.

In some embodiments, the reaction chamber 224 may be optimized such that deposition or synthesis of the carbon-containing solids occurs only on the substrate and not on the walls of the chamber itself. In some embodiments the walls 224 may be coated with a material to prevent the conversion of carbon monoxide to solid carbon materials. In some embodiments, the walls 214 of the chamber 224 may be coated or lined with a material that prevents deposition or synthesis of the carbon structures. In some embodiments, the coating may be a substantially inert or non-reactive material or metal. In some embodiments, the coating or lining may be engineered to withstand the high temperatures of the plasma process. In some embodiments, the coating may be a metallic coating, a glass coating, a ceramic coating, a thermoplastic or plastic coating, a self-assembled monolayer or coating, or a metallic alloy coating.

The carbon-containing solids produced according to methods herein may be removed from the bottom of the chamber or from the side of the chamber. Similarly, gasses or gaseous byproducts may be removed from the chamber 224 through a side port 226. The side port 226 may contain a filter to prevent the removal of unwanted solid particles or gaseous byproducts though the side port 226. In some embodiments, the removal of gasses may be driven by a pneumatic pump. In some embodiments the reaction chamber 224 may be under a vacuum prior to the injection of the microwave plasma gasses to prevent unwanted gasses and reduce the filter or separation of product gasses that are removed from the microwave plasma chamber. In some embodiments the reaction chamber 224 may be hermetically sealed to reduce the contamination of atmospheric gasses with gaseous products.

In some embodiments, the gasses sent through the side port 226 may be separated in a gas separator 208, although a gas separator is not required. In some embodiments, the gas separator 208 may separate oxygen (O₂) or carbon monoxide (CO) from other gaseous byproducts such as unreacted carbon-containing gasses. In some embodiments, the gas separator 208 may enrich or purify the oxygen gas or carbon monoxide gas to provide the oxygen or carbon monoxide to a gaseous product exhaust port 210. In some embodiments, the gaseous product exhaust port 210 may be used to capture the purified or enriched gas in small quantities or in bulk, and the resulting gas may be containerized for later use or resale or circulated to other plasma reaction processes.

In some embodiments, carbon monoxide, carbon dioxide, other carbon-containing gasses, and/or oxygen may be recycled back into a gas recycling port 206 to provide the reactive gasses back into the reaction chamber 224. Alternatively, or in combination with the recycling port 206, the gaseous byproducts may be sent back to the additional injection port 202 via a recycling line connected to ports 228. In some embodiments, this enables a zero-waste process where all of the reactants are converted into desirable products or recycled back into the system.

In some embodiments the thermal decomposition reaction may be configured to generate CO (g) as a product of the reaction, such that a lesser portion or none of the CO (g) is converted to solid carbon. For example, CO (g) may be removed from the reaction chamber via side port 226 and collected on a container or vessel to package, sell, or use in different processes. Thus, CO (g) may be configured as the product of the microwave plasma apparatus 200. In such embodiments the reaction pathway may generally depicted as 2CO₂ (g)→2CO (g)+O₂ (g). In some embodiments CO (g) and O₂ (g) may both be collected as products of the reaction. In some embodiments only one of CO (g) and O₂ (g) may be collected while the other may be discarded or recycled back into the system to be reinserted in the reaction chamber. In some embodiments the system may be optimized for the synthesis of solid carbon and CO (g) as the products of the microwave pyrolysis reaction.

FIG. 3 illustrates an additional embodiment of the disclosed process. FIG. 3 generally depicts a plasma apparatus 300 that may be configured to operate under atmospheric pressure. In some embodiments, a substrate is not provided in the reaction chamber 310 of the plasma apparatus 300. Instead, in some embodiments, one or more of the walls 308 of the reaction chamber 310 may be coated or lined with a catalyst to facilitate the growth of the carbon solids, such as CNTs, MWCNTs, and graphene. In some embodiments, a portion of the one or more walls 308 is coated with the catalyst material, but in various other embodiments ⅛, ¼, ⅓, ½, ¾, or the entirety of the reaction chamber may be coated with the catalyst material. In some embodiments, a portion of the one or more chamber walls 308 is coated or lined with a catalyst such that the deposited material may be collected in the collection section 306 of the chamber 310 under the force of gravity or tension. Alternatively, in some embodiments, the deposited material may be collected on the collection section 306 through vibration, air currents, etc. In some embodiments the coating may prevent the deposition of carbon containing materials such that only gaseous byproducts are produced, such as carbon monoxide (CO) or oxygen (O₂).

In some embodiments of the plasma apparatus 300, the deposition of the solid carbon materials, such as CNTs, MWCNTs, and graphene, may by facilitated by a roll-to-roll process. In some embodiments, the roll-to-roll process may be continuous or substantially continuous such that the solid carbon materials may be produced in bulk. In various embodiments, the carbon material may be deposited in a single phase or step, such that the pyrolyzed carbon is substantially incorporated into the solid carbon structure in a single phase reaction. For example, while not being bound by any specific theory, the carbon material may be integrated layer-by-layer or section-by-section, or carbon atom upon carbon atom from gaseous carbon monoxide. In some embodiments, producing materials in a continuous or semi-continuous manner is advantageous as it provides a lower cost of production for the solid carbon-containing material. In some embodiments, the solid carbon-containing materials, such as graphene CNTs, or MWCNTs, may be deposited on a catalyzing substrate perpendicular or parallel to one or more chamber walls 308 of the plasma apparatus 300. The catalyzing substrate may substantially span the diameter or width of the chamber 310 to facilitate deposition of solid carbon materials thereon. The catalyzing substrate may be configured as a belt or roll and a collection section 306 may be provided with a belt, roll, or spool to collect the material deposited on the catalyzing substrate and the belt or roll may roll up the material in a sheet, string, template, layer, or strings as it is deposited. In some embodiments the roll is unrolled on one side of the chamber 310 and the roll is rolled up on the opposite side of the chamber 310. In some embodiments the belt or roll contains catalyzing metals, such as transition metals, for the deposition of sp² carbons thereon, and in some instances the catalyzing materials may be provided as particles attached to or deposited on the roll. In some embodiments, the collection section 306 may contain a cylinder, funnel, guide, belt, conveyor, or other material to facilitate the collection of the solid carbon material. In various embodiments, the collection section 306 is cooled or provided with a material to withstand the high temperatures within the chamber 310. Similarly, a belt or roll may be provided with a cooling mechanism to withstand the temperatures in the chamber 310.

In some embodiments the walls may be lined with an anti-stick or anti-deposition coating that prevents the deposition or sticking of solid carbon materials thereon. For example, the walls may be provided with a coating to prevent the deposition of nanometer-sized catalytic material thereon. In some embodiments, the catalytic material or alloy may be substantially the same as that described for FIG. 2, such as a transition metal or post-transitional metal or alloy. In some embodiments, the lining of the one or more chamber walls 308 is different in regions of the pyrolysis sections of the chamber 310 and the deposition region of the chamber 310. For example, in some embodiments, the pyrolysis region of the chamber 310 may comprise a quartz liner or a quartz tube and the deposition region or portions of the deposition region may be lined with a catalyst for deposition of solid carbon materials, such as CNTs, MWCNTs, or graphene.

In some embodiments, gas may be injected into the system via port 304. In some embodiments, a carbon-containing gas, such as carbon dioxide or carbon monoxide, is provided via port 304 and an enabling gas or a catalyzing substrate is provided via additional port 302. The enabling gas and the carbon-containing gas may be the same as those provided with regard to FIG. 3. The enabling gas may be a hydrogen-containing gas or gas vapor such as elemental hydrogen (H₂), methane (CH₄), carbon monoxide (CO), ethylene (C₂H₄), propane (C₃H₈), butane (C₄H₁₀), acetylene (C₂H₂), propylene (C₃H₆), isobutane (C₄H₁₀), benzene (C₆H₆), ethane (C₂H₆), formaldehyde (CH₂O), dimethyl ether (C₂H₆O), ethanol (C₂H₅OH), methanol (CH₃OH), ethyne (C₂H₂), methyl mercaptan (CH₃SH), ethyl mercaptan (C₂H₅SH), carbon disulfide (CS₂), phosgene (COCl₂), acetaldehyde (C₂H₄O), acetic acid (C₂H₄O₂), acetone (C₃H₆O), acetonitrile (CH₃CN), carbon tetrachloride (CCl₄), dichloromethane (CH₂Cl₂), toluene (C₇H₈), xylene (C₈H₁₀), ethylbenzene (C₈H₁₀), styrene (C₈H₈), phenol (C₆H₆O), propionic acid (C₃H₆O₂), acrylonitrile (C₃H₃N), formic acid (CH₂O₂), propionaldehyde (C₃H₆O), dimethylamine (C₂H₇N), pyridine (C₅H₅N), and furan (C₄H₄O), among others. Hydrogen containing gasses may function to sequester O₂ such that it does not recombine with carbon in the chamber 310 to create carbon monoxide or carbon dioxide. In such a process the oxygen and hydrogen may combine to create a stable, low energy molecule. In some instances water or water vapor may be produced to sequester the oxygen. The water may be condensed inside or outside of the reaction chamber and separated from other gasses or solids.

In some embodiments, gasses or materials may be discharged from the plasma apparatus 300 via outlet 312. For example, carbon monoxide, fuel, syngas, or other byproducts may be discharged from the plasma apparatus 300 via outlet 312. In some embodiments, these gasses or byproducts may be recycled back into the port 304 or additional port 302. In some embodiments CO (g) may be siphoned off or removed from the reaction chamber as the product of the microwave plasma reaction. In some embodiments the system may be configured to produce CO (g) and solid carbon as a product of the microwave plasma reaction.

FIG. 3B illustrates an additional embodiment of the disclosed process. In this embodiment the microwave plasma apparatus is inverted such that the gas feed may be vertically below the microwave plasma chamber 310. Carbon dioxide may be injected via port 304 and/or an enabling gas may be injected via additional port 302. As with other embodiments, the gas is heated via microwave energy and sent through processing region 316 and deposited as solid carbon particles in deposition region 318. The gas injected via port 304 and/or additional port 302 may create an upward force in the chamber 310. This enables the gas to flow through the module or substrate 320 to create a fluidized bed. The module or substrate itself may have a catalyzing material or the module or substrate may have catalyzing material that is suspended on it or fluidized above it. In such a scenario, the module or substrate 320 contains pores sufficiently large for the penetration of gasses but small enough that the catalyzing material does not fall through. In some embodiments the module or substrate 320 is a grid, lattice, or tortuous path. In some embodiments the catalyzing material is about 1 to about 5 nanometers in diameter. In other embodiments the catalyzing substrate is about 0.1 nm to about 20 nm, about 1 nm to about 15 nm, about 1 nm to about 12 nm, about 1 nm to about 10 nm, about 1 nm to about 7 nm, about 2 nm to about 6 nm, about 3 nm to about 5 nm and any range in between. In some embodiments the catalyzing material is composed of catalyzing particles that are spherical, oblong, almond shaped, substantially planar, or planar. The catalyzing particles may be about 1 nm to about 5 nm in diameter or about 1 nm to 5 nm in thickness. The composition of the catalyzing material may be the same as that discussed with regard to FIG. 2.

In some embodiments the catalyzing particles may be provided into the microwave plasma apparatus in dimensions that will be further reduced through exposure to the plasma. For example, the catalyzing particles may be provided into the plasma in the range of about 50 nm to 900 microns and are reduced to a size of about 1 to 40 nm, or 1 to 5 nm, through exposure to the plasma. For example, micron-sized MWCNT catalyst may be fed on top of the torch or through the torch and converted to a nanometer-sized SWCNT catalyst in single gas to solid phase or step. For example, the solid carbon materials may be converted via carbon deposited from gaseous carbon monoxide particles.

The deposition region 318 of the chamber 310 may have one or more entrance and exit ports (not shown) for the continuous addition of catalyzing particles and the continuous removal of solid carbon and catalyzing particles deposited in the presence of the catalyzing particles. In an alternative embodiment the catalyzing particles are added and removed in a batchwise process. Alternatively the addition and removal may be in a semi-batchwise process. The fluidization region of the catalyzing particles is generally shown as 322 in FIG. 3B. Gaseous byproducts may be removed via outlet 312, such as a byproduct of oxygen-rich gas or carbon monoxide gas. Additionally, in some embodiments fluidized particles, such as solid carbon materials, may be removed via outlet 312.

In some embodiments the chamber 310 may be configured with an outlet, such as discussed previously, for the removal of byproducts or gasses. In some embodiments the chamber 310 may be configured to produce CO (g) as a product of the microwave pyrolysis reaction. CO (g) may be removed as the product of the pyrolysis reaction in addition to or instead of solid carbon as the primary product.

Any of the embodiments provided herein may be provided with sensors to monitor, adjust, and provide feedback for the microwave heating or deposition process. In some embodiments the microwave apparatus may be provided with one or more Thermo-Couples (TC), one or more Optical Emission Spectroscopy (OES) sensors, or one or more Residual Gas Analyzers (RGA). These sensors may provide a non-intrusive way to measure the reaction parameters. For example, the one or more Optical Emission Spectroscopy sensors may provide a non-intrusive, qualitative measure of plasma/gas composition, such as in the active plasma region. The one or more Thermo-Couples may provide a quantitative measure of the gas/solid temperature, which can be indicative gas to solid conversion. Finally, the one or more Residual Gas Analyzers may provide a quantitative measure of gas composition. In some embodiments the RGA is provided close to a chamber exit of the reaction chamber. In some embodiments the TC or OES sensors may be provided to measure through a window of one of the walls of the reaction chamber such that the sensor may non-intrusively measure the parameters of the reaction chamber. In other embodiments the sensors or a portion of the sensors may be provided in the reaction chamber, and the sensors may be lined with a material that prevents deposition of the solid carbon on the sensors. In some embodiments the reaction chamber is provided with a pressure sensor for the regulation of gas pressures in the reaction chamber.

In some embodiments the sensors are provided in an open loop or closed feedback loop to automatically adjust parameters in the apparatus. For example, the sensors may be in communication with the ports for the injection of gasses to increase or decrease gas injection or in communication with the microwave plasma propagator or waveguide. In this manner the sensors may automatically adjust the parameters of the deposition process, such as temperature, pressure, gas flow, gas composition, etc. The sensors may also be in communication with an injection port for the addition of catalytic particles.

The temperature of the plasma and the reaction chamber may be monitored to optimize the growth of the nanoparticles. In various embodiments the plasma may be regulated to a temperature of 4000 to 7000 Kelvin or preferably about 5000 to 6000 Kelvin. Thermodynamic analysis shows that more than 99% of carbon dioxide is converted to carbon monoxide and oxygen at a temperature of about 6000 K. The temperature range for the deposition region of the reaction chamber may be regulated such that it is in the range of 300 to 1500 degrees Celsius, or about 500 to 1200 degrees Celsius.

Any of the embodiments herein may incorporate a catalytic activation step. In this step, an activating gas may be provided in the reaction chamber in order to prime or activate the catalyst for growth of solid carbons thereon. The catalytic activation step may comprise the injection of a reducing gas, such as hydrogen, into the reaction chamber. The reducing gas may be mixed with a noble gas, such as helium, neon, or argon. In some embodiments the activating gas may reduce the transition metal oxidation state such as to provide the transition metal in an active state. In some embodiments the activation step may be performed periodically such that the chamber is purged and provided with a reducing gas upon the addition of additional catalytic material or where deposition data indicates that the catalyst has been poisoned or otherwise reduced in catalytic potential.

### Microwave Plasma Apparatus

In some embodiments, a microwave plasma apparatus may be used in the production of carbon structures according to the embodiments herein. In some embodiments, the microwave plasma apparatus may comprise a microwave generator for generating microwaves at a frequency between 300 MHz and 300 GHz, such as, for example, 915 Mhz.

In some embodiments, the microwave plasma apparatus may comprise a gas mixing panel, plasma torch with quartz liner, water-cooled stainless-steel reactor, water cooled exhaust and water separation particle filter. In some embodiments monitoring instrumentation may be provided, including a machine vision camera, one or more thermocouples, one or more inspection ports, such as at the liner exit, and mass spectrometer, such as in the exhaust after the water-cooled sections.

In some embodiments, an extension tube may be provided. The extension tube may be a graphite tube, or a tube lined with a material to prevent deposition of materials thereon. In some embodiments, the extension tube extends downward into a reaction chamber of the microwave plasma apparatus, the extension tube confining and directing the microwave plasma to extend its length. In some embodiments, the extension tube may concentrate the energy and power provided by a microwave power source, in order to form a longer microwave plasma within the apparatus. The methods and apparatuses described herein may utilize an extension tube, which extends downward from a core plasma tube into the reaction chamber. In some embodiments, the extension tube may concentrate energy from the microwave power source into a smaller volume, extending and directing the plasma at a greater length than would be possible using a conventional microwave plasma apparatus. In some embodiments, a length of a plasma may be tuned or altered by configuring one or more of the following parameters: power, plasma gas flow, type of gas, extension tube material, level of insulation of the reactor chamber or the extension tube, level of coating of extension tube, and geometry of the extension tube (e.g., tapered/stepped).

Furthermore, in some embodiments, a lining, an agitator, vibrator, or other device may be provided to prevent sticking and/or to remove feedstock particles from surfaces of the extension tube. In some embodiments, providing an extension tube with a specific shape may facilitate prevention of material accumulation on one or more surfaces of the microwave plasma torch. For example, a conical extension tube may prevent buildup on surfaces of the extension tube.

In some embodiments, an extension tube as described herein may extend downward into the reaction chamber of a microwave plasma apparatus. In some embodiments, the extension tube may extend downward at a length of at least 5%, at least 10%, at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, or at least 100% of the reaction chamber length, or any value between the aforementioned values.

Various parameters of the microwave plasma may be adjusted manually or automatically in order to achieve a desired material. These parameters may include, for example, power, plasma gas flow rates, type of plasma gas, presence of an extension tube, extension tube material, level of insulation of the reactor chamber or the extension tube, level of coating of the extension tube, geometry of the extension tube (e.g. tapered/stepped), feed material size, feed material insertion rate, feed material inlet location, feed material inlet orientation, number of feed material inlets, plasma temperature, residence time and cooling rates. The resulting material may exit the plasma into a sealed chamber where the material is quenched then collected. In some embodiments, the extension tube may comprise isomolded graphite and be held up by, for example, a stainless sheet scaffold. In some embodiments, the top edge of the extension tube may be machined to fit over the quartz liner to create a seamless extension of the plasma containment.

In some embodiments, the microwave plasma apparatus may be operated at atmospheric pressure (760 Torr). In some embodiments, before running, the chamber may be purged to below 100 ppm oxygen using argon gas before striking plasma. In some embodiments, after processing and once the chamber temperature has fallen below 50° C., compressed dry air (CDA) may be slowly added in 5 vol % increments with Argon until 100 vol % CDA fills the chamber.

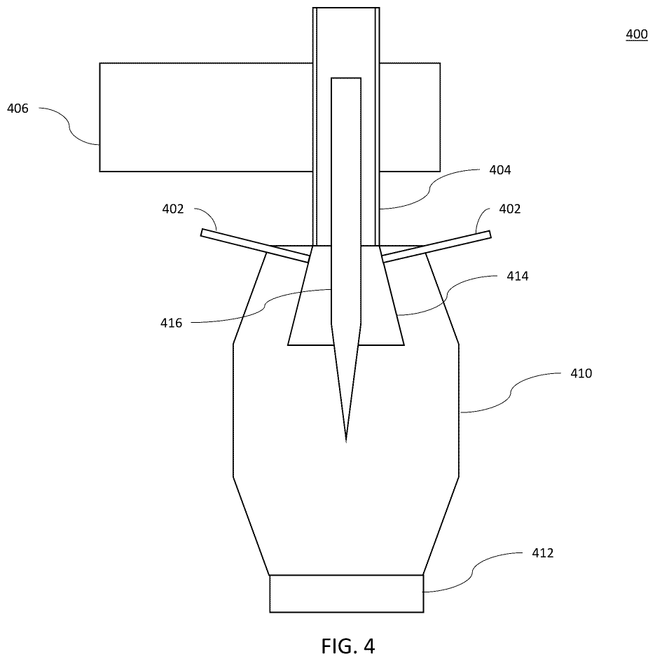

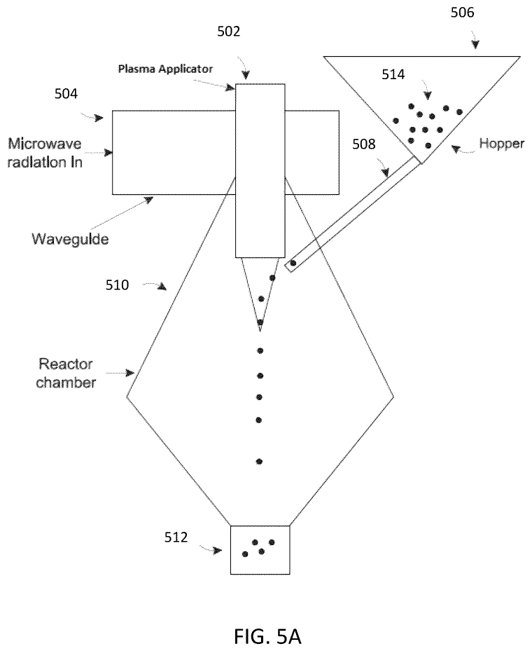

FIG. 4 illustrates an embodiment of a microwave plasma torch 400 that can be used in the production of materials according to some embodiments herein. In some embodiments, a feedstock can be introduced, via one or more feedstock inlets 402, into a microwave plasma 416. In some embodiments the feedstock may be catalyzing particles or substrates that are microns or nanometers in diameter. In some embodiments, an entrainment gas flow and/or a sheath flow may be injected into the microwave plasma torch 400 to create flow conditions within the plasma torch prior to ignition of the plasma 416 via microwave radiation source 406. In some embodiments, the entrainment flow and sheath flow are both axis-symmetric and laminar, while in other embodiments the gas flows are swirling. In some embodiments, the feedstock may be introduced into the microwave plasma torch 400, where the feedstock may be entrained by a gas flow that directs the materials toward the plasma 416.

The gas flows can comprise a noble gas column of the periodic table, such as helium, neon, argon, etc. Although the gases described above may be used, it is to be understood that a variety of gases can be used depending on the desired material and processing conditions, such as carbon-containing gasses. In some embodiments, within the microwave plasma 416, the feedstock may undergo a physical and/or chemical transformation. Inlets 402 can be used to introduce process gases to entrain and accelerate the feedstock towards plasma 416. In some embodiments, a second gas flow can be created to provide sheathing for the inside wall of a core gas tube or liner 404 and a reaction chamber 410 to protect those structures from melting due to heat radiation from plasma 416.

Various parameters of the microwave plasma 416 may be adjusted manually or automatically in order to achieve a desired material. These parameters may include, for example, power, plasma gas flow rates, type of plasma gas, presence of an extension tube, extension tube material, level of insulation of the reactor chamber or the extension tube, level of coating of the extension tube, geometry of the extension tube (e.g. tapered/stepped), feed material size, feed material insertion rate, feed material inlet location, feed material inlet orientation, number of feed material inlets, plasma temperature, residence time and cooling rates. The resulting material may exit the plasma into a sealed chamber 412 where the material is quenched then collected.

In some embodiments, the feedstock is injected after the microwave plasma torch applicator for processing in the “plume” or “exhaust” of the microwave plasma torch. Thus, the plasma of the microwave plasma torch is engaged at the exit end of the plasma torch core tube 108, or further downstream. In some embodiments, adjustable downstream feeding allows engaging the feedstock or catalytic particles with the plasma plume downstream at a temperature suitable for optimal melting of feedstock through precise targeting of temperature level and residence time. Adjusting the inlet location and plasma characteristics may allow for further customization of material characteristics. Furthermore, in some embodiments, by adjusting power, gas flow rates, pressure, and equipment configuration (e.g., introducing an extension tube), the length of the plasma plume may be adjusted.

In some embodiments, feeding configurations may include one or more individual feeding nozzles surrounding the plasma plume. The feedstock may enter the plasma from any direction and can be fed in 360° around the plasma depending on the placement and orientation of the inlets 402. Furthermore, the feedstock may enter the plasma at a specific position along the length of the plasma 416 by adjusting placement of the inlets 402, where a specific temperature has been measured and a residence time estimated for providing the desirable characteristics of the resulting material.

In some embodiments, the angle of the inlets 402 relative to the plasma 416 may be adjusted, such that the feedstock can be injected at any angle relative to the plasma 416. For example, the inlets 102 may be adjusted, such that the feedstock may be injected into the plasma at an angle of about 0 degrees, about 5 degrees, about 10 degrees, about 15 degrees, about 20 degrees, about 25 degrees, about 30 degrees, about 35 degrees, about 40 degrees, about 45 degrees, about 50 degrees, about 55 degrees, about 60 degrees, about 65 degrees, about 70 degrees, about 75 degrees, about 80 degrees, about 85 degrees, or about 90 degrees relative to the direction of the plasma 416, or between any of the aforementioned values.

In some embodiments, implementation of the downstream injection method may use a downstream swirl or quenching. A downstream swirl refers to an additional swirl component that can be introduced downstream from the plasma torch to keep the powder from the walls of the core tube 404, the reactor chamber 410, and/or an extension tube 414.

In some embodiments, the extension tube may extend into the reaction chamber of a microwave plasma apparatus. In some embodiments, the extension tube may comprise a stepped shape, such that the tube comprises one or more cylindrical volumes extending downward in the reaction chamber, wherein each successive cylindrical volume comprises a larger diameter than each previous cylindrical volume as the tube extends downward in the reaction chamber. In some embodiments, the extension tube may have a conical shape, tapering radially outwards as it extends downward into the reaction chamber. In some embodiments, the extension tube may comprise a single cylindrical volume.

In some embodiments, the extension tube may have a dual conical shape, where the first conical shape tapers radially outwards as it extends downward into the rection chamber, and the second conical shape is an inverted asymmetrical shape to the first conical shape and is connected to the end of the first conical shape and tapers radially inwards as it extends downward into the reaction chamber. In some embodiments, the extension tube may comprise a dual conical shape, where the widest portion of the first conical shape is connected to the widest portion of the second conical shape. In some embodiments, the length of the first conical shape is greater than the length of the second conical shape.

In some embodiments, the extension tube may have a dual conical shape, where the first conical shape tapers radially outwards as it extends downward into the reaction chamber and the second conical shape is an inverted symmetrical shape to the first conical shape and is connected to the end of the first conical shape and tapers radially inwards as it extends downward into the reaction chamber. In some embodiments, the widest portion of the first conical shape is connected to the widest portion of the second conical shape. In some embodiments, the length of the first conical shape is equal to the length of the second conical shape. In some embodiments, the length of the second conical shape is greater than the length of the first conical shape. In some embodiments, the feed material inlets may insert feedstock within the extension tube.

In some embodiments, the extension tube may comprise a length of about 1 foot. In some embodiments, the extension tube may comprise a length of about 1 inch, about 2 inches, about 3 inches, about 4 inches, about 5 inches, about 6 inches, about 7 inches, about 8 inches, about 9 inches, about 10 inches, about 11 inches, about 1 foot, about 2 feet, about 3 feet, about 4 feet, about 5 feet, about 6 feet, about 7 feet, about 8 feet, about 9 feet, about 10 feet, about 11 feet, about 12 feet, about 13 feet, about 14 feet, about 15 feet, about 16 feet, about 17 feet, about 18 feet, about 19 feet, about 20 feet, about 21 feet, about 22 feet, about 23 feet, about 24 feet, about 25 feet, about 26 feet, about 27 feet, about 28 feet, about 29 feet, or about 30 feet, or any value between the aforementioned values.

In some embodiments, the length of a reaction chamber 410 of a microwave plasma apparatus may be about 1 foot, about 2 feet, about 3 feet, about 4 feet, about 5 feet, about 6 feet, about 7 feet, about 8 feet, about 9 feet, about 10 feet, about 11 feet, about 12 feet, about 13 feet, about 14 feet, about 15 feet, about 16 feet, about 17 feet, about 18 feet, about 19 feet, about 20 feet, about 21 feet, about 22 feet, about 23 feet, about 24 feet, about 25 feet, about 26 feet, about 27 feet, about 28 feet, about 29 feet, or about 30 feet, or any value between the aforementioned values.

In some embodiments, the length of the plasma 416, which may be extended by adjusting various processing conditions and equipment configurations, may be about 1 foot, about 2 feet, about 3 feet, about 4 feet, about 5 feet, about 6 feet, about 7 feet, about 8 feet, about 9 feet, about 10 feet, about 11 feet, about 12 feet, about 13 feet, about 14 feet, about 15 feet, about 16 feet, about 17 feet, about 18 feet, about 19 feet, about 20 feet, about 21 feet, about 22 feet, about 23 feet, about 24 feet, about 25 feet, about 26 feet, about 27 feet, about 28 feet, about 29 feet, or about 30 feet, or any value between the aforementioned values.

In some embodiments, the entrainment flow and sheath flow are both axis-symmetric and laminar, while in other embodiments the gas flows are swirling. The feed materials may be introduced axially into the microwave plasma torch, where they are entrained by a gas flow that directs the materials toward the plasma. Within the microwave generated plasma, the feed materials may be melted or partially melted in order to spheroidize the materials. Inlets can be used to introduce process gases to entrain and accelerate particles towards the plasma. In some embodiments, particles are accelerated by entrainment using a core laminar gas flow created through an annular gap within the plasma torch. A second laminar flow can be created through a second annular gap to provide laminar sheathing for the inside wall of dielectric torch to protect the wall from melting due to heat radiation from plasma. In some embodiments, the laminar flows direct particles toward the plasma along a path as close as possible to a central axis of the plasma, exposing the particles to a substantially uniform temperature within the plasma.

In some embodiments, suitable flow conditions are present to keep particles from reaching the inner wall of the plasma torch where plasma attachment could take place. In some embodiments, particles are guided by the gas flows towards the microwave plasma, where each particle undergoes homogeneous thermal treatment. Various parameters of the microwave generated plasma, as well as particle parameters, may be adjusted in order to achieve desired results. These parameters may include microwave power, feed material size, feed material insertion rate, gas flow rates, plasma temperature, residence time and cooling rates. In some embodiments, the cooling or quenching rate is not less than 10⁺³ degrees C./sec upon exiting the plasma. As discussed above, in some embodiments, the gas flows are laminar; however, in alternative embodiments, swirl flows or turbulent flows may be used to direct the feed materials toward the plasma.

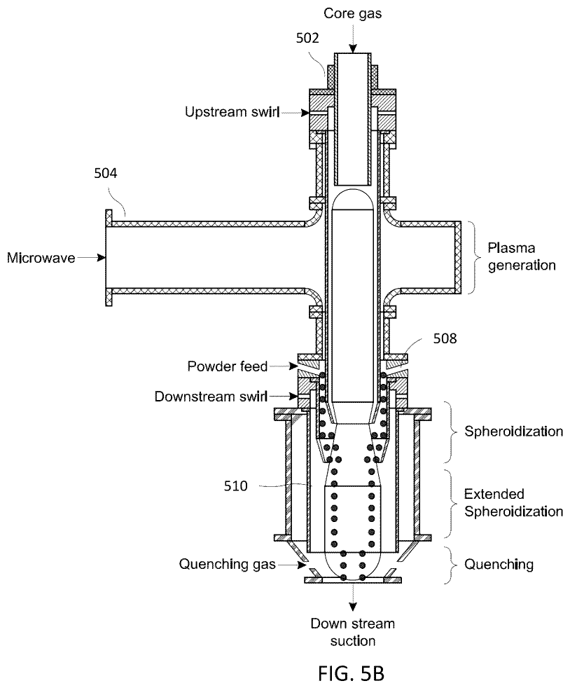

FIGS. 5A-B illustrate an exemplary microwave plasma torch that includes a side feeding hopper, thus allowing for downstream feeding, such as downstream feeding of a catalyzing particle or substrate. Thus, in this implementation the feedstock is injected after the microwave plasma torch applicator for processing in the “plume” or “exhaust” of the microwave plasma torch. Thus, the plasma of the microwave plasma torch is engaged at the exit end of the plasma torch to allow downstream feeding of the feedstock. This downstream feeding can advantageously extend the lifetime of the torch as the hot zone is preserved indefinitely from any material deposits on the walls of the hot zone liner. Furthermore, it allows engaging the plasma plume downstream at temperature suitable for optimal processing of powders through precise targeting of temperature level and residence time. For example, there is the ability to dial the length of the plume using microwave powder, gas flows, and pressure in the quenching vessel that contains the plasma plume.

Other feeding configurations may include one or several individual feeding nozzles surrounding the plasma plume. The feedstock powder can enter the plasma at a point from any direction and can be fed in from any direction, 360° around the plasma, into the point within the plasma. The feedstock powder can enter the plasma at a specific position along the length of the plasma plume where a specific temperature has been measured and a residence time estimated for sufficient melting of the particles. The melted particles exit the plasma into a sealed chamber where they are quenched then collected.

The feed materials 514 can be introduced into a microwave plasma torch 502. A hopper 506 can be used to store the feed material 514 before feeding the feed material 514 into the microwave plasma torch 502, plume, or exhaust. The feed material 514 can be injected at any angle to the longitudinal direction of the plasma torch 502, such as at 5, 10, 15, 20, 25, 30, 35, 40, 45, 50, 55 degrees, or any value between the aforementioned values. In some embodiments, the feedstock can be injected an angle of greater than 5, 10, 15, 20, 25, 30, 35, 40, 45, 50, or 55 degrees. In some embodiments, the feedstock can be injected an angle of less than 5, 10, 15, 20, 25, 30, 35, 40, 45, 50, or 55 degrees. In alternative embodiments, the feedstock can be injected along the longitudinal axis of the plasma torch.

The microwave radiation can be brought into the plasma torch through a waveguide 504. The feed material 514 may be fed into a plasma chamber 510 and may be placed into contact with the plasma generated by the plasma torch 502. When in contact with the plasma, plasma plume, or plasma exhaust, the feed material may melt. While still in the plasma chamber 510, the feed material 514 cools and solidifies before being collected into a container 512. Alternatively, the feed material 514 can exit the plasma chamber 510 while still in a melted phase and cool and solidify outside the plasma chamber. In some embodiments, a quenching chamber may be used, which may or may not use positive pressure. While described separately from FIG. 1, the embodiments of FIGS. 5A and 5B are understood to use similar features and conditions to the embodiment of FIG. 4.

In some embodiments the catalyzing particles may be provided into the microwave plasma apparatus in dimensions that will be further reduced through exposure to the plasma. For example, the catalyzing particles may be provided into the plasma in the range of about 50 nm to 900 microns, about 500 nm to 900 microns, about 800 nm to 900 microns, about 1 micron to 900 microns and are reduced to a size of about 1 to 40 nm, or about 1 to about 5 nm, through exposure to the plasma torch. For example, micron-sized MWCNT catalyst may be fed on top of the torch or through the torch and converted to a nanometer-sized SWCNT catalyst in single step.

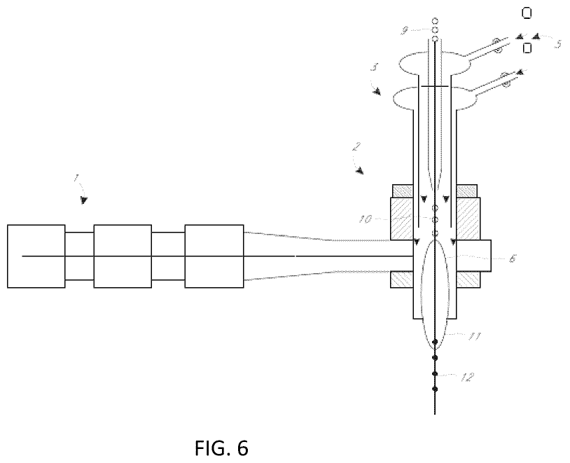

FIG. 6 illustrates an exemplary microwave plasma torch that can be used in the production of materials, according to embodiments of the present disclosure. Feed materials, such as a carbon-containing gas 9, 10 can be introduced into a microwave plasma torch 2 in an introduction zone 3, the torch sustaining a microwave-generated plasma 11. In one example embodiment, an entrainment gas flow and a sheath flow (downward arrows) may be injected through inlets 5 to create flow conditions within the plasma torch 2 prior to ignition of the plasma 11 via microwave radiation source 1.

In some embodiments, the entrainment flow and sheath flow are both axisymmetric and laminar, while in other embodiments the gas flows are swirling. The feed materials 9 may be introduced axially into the microwave plasma torch 2, where they are entrained by a gas flow that directs the materials toward the plasma hot zone 6. The gas flows can consist of carbon-based gases, CO₂, or a noble gas column of the periodic table, such as helium, neon, argon, etc. Within the microwave-generated plasma, the feed materials are spheroidized, pyrolyzed, and/or ionized. Inlets 5 can be used to introduce process gases to entrain and accelerate material or particles 9, 10 along axis 12 towards plasma 11. First, particles 9 are accelerated by entrainment using a core laminar gas flow (upper set of arrows) created through an annular gap within the plasma torch. A second laminar flow (lower set of arrows) can be created through a second annular gap to provide laminar sheathing for the inside wall of dielectric torch to protect it from melting due to heat radiation from plasma 11. In exemplary embodiments, the laminar flows direct particles 9, 10 toward the plasma 11 along a path as close as possible to axis 12, exposing them to a substantially uniform temperature within the plasma.

In some embodiments, suitable flow conditions are present to keep particles 10 from reaching the inner wall of the plasma torch 2 where plasma attachment could take place. Particles 9, 10 may be guided by the gas flows towards microwave plasma 11 were each undergoes homogeneous thermal treatment. The particles may be substrate materials for catalytic conversion of carbon-containing gasses to solid carbons. Various parameters of the microwave-generated plasma, as well as particle parameters, may be adjusted in order to achieve desired results. These parameters may include microwave power, feed material size, feed material insertion rate, gas flow rates, plasma temperature, residence time and cooling rates. In some embodiments, the cooling or quenching rate is not less than 10+3 degrees C./sec upon exiting plasma 11. As discussed above, in this particular embodiment, the gas flows are laminar; however, in alternative embodiments, swirl flows or turbulent flows may be used to direct the feed materials toward the plasma.

### Microwave Plasma Processing

In a microwave plasma process, the feedstock may be entrained in an inert and/or reducing gas environment and injected into the microwave plasma, the microwave plasma plume, or the microwave plasma exhaust. Upon injection into a hot plasma (or plasma plume or exhaust), the feedstock may undergo a physical and/or chemical transformation (e.g., spheroidization). After processing, the resulting material may be released into a chamber filled with an inert gas and directed into hermetically sealed drums where is it stored. This process can be carried out at atmospheric pressure, in a partial vacuum, or at a slightly higher pressure than atmospheric pressure.

In alternative embodiments, the process can be carried out in a low, medium, or high vacuum environment. For example, the microwave plasma chamber may be sealed prior to injecting gasses for the production of microwave plasma. The process can run in batches or continuously, with the drums being replaced as they fill up with processed material. By controlling the process parameters, such as cooling gas flow rate, residence time, plasma conditions, cooling gas composition, various material characteristics can be controlled.

Residence time of the particles or gasses within a hot zone of the plasma can also be adjusted to provide control over the resulting material characteristics. That is, the length of time the particles are exposed to the plasma determines the extent of melting of the feedstock particles (i.e., surface of the particle melted as compared to the inner most portion or core of the particle). Residence time can be adjusted by adjusting such operating variables of particle injection rate and flow rate (and conditions, such as laminar flow or turbulent flow) within the hot zone. Equipment changes can also be used to adjust residence time. For example, residence time can be adjusted by changing the cross-sectional area of the plasma, by, for example, extending the plasma. In some embodiments, extending the plasma may comprise incorporating an extension tube into the microwave plasma apparatus.

In some embodiments, the extension tube may comprise a stepped shape, such that the tube comprises one or more cylindrical volumes extending downward in the reaction chamber, wherein each successive cylindrical volume comprises a larger diameter than each previous cylindrical volume as the tube extends downward in the reaction chamber. In some embodiments, the extension tube may have a conical shape, tapering radially outwards as it extends downward into the reaction chamber. In some embodiments, the extension tube may comprise a single cylindrical volume4. In some embodiments, the feed material inlets may insert feedstock within the extension tube.

In some embodiments, the extension tube may comprise a length of about 1 foot. In some embodiments, the extension tube may comprise a length of about 1 inch, about 2 inches, about 3 inches, about 4 inches, about 5 inches, about 6 inches, about 7 inches, about 8 inches, about 9 inches, about 10 inches, about 11 inches, about 1 foot, about 2 feet, about 3 feet, about 4 feet, about 5 feet, about 6 feet, about 7 feet, about 8 feet, about 9 feet, about 10 feet, about 11 feet, about 12 feet, about 13 feet, about 14 feet, about 15 feet, about 16 feet, about 17 feet, about 18 feet, about 19 feet, about 20 feet, about 21 feet, about 22 feet, about 23 feet, about 24 feet, about 25 feet, about 26 feet, about 27 feet, about 28 feet, about 29 feet, or about 30 feet, or any value between the aforementioned values.

In some embodiments, the feedstock particles are exposed to a temperature profile at between 4,000 and 8,000 K within the microwave plasma. In some embodiments, the particles are exposed to a temperature profile at between 3,000 and 8,000 K within the microwave plasma. In some embodiments, one or more temperature sensors may be located within the microwave plasma torch to determine a temperature profile of the plasma.

### Carbon Nanocages

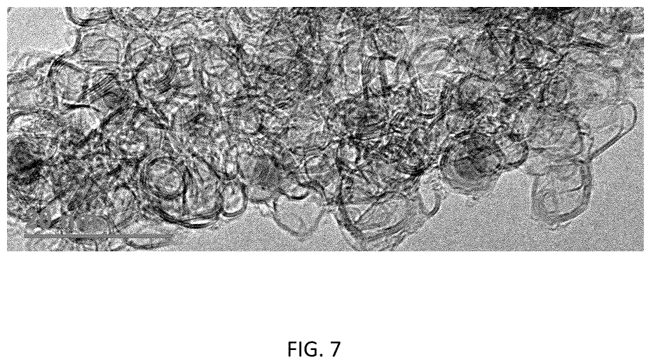

In some embodiments the methods disclosed herein may be used to produce nanocages, such as those shown in FIG. 7, which has a scale of 20 nm (shown in the bottom left corner). Carbon nanocages are generally comprised of a kind of spherical nanocarbon with a graphitic shell and a hollow interior. The carbon nanocages may be generally non-crystalline as a whole on the atomic scale but have order in one or more graphitic layers of the nanocage. The nanocages may be comprised of solid carbon that is deposited in the microwave plasma processes disclosed herein. The generally hollow cage-like structures on the nano-scale contain microchannels through which materials may be inserted, entrapped, or sequestered. The channels in the nanocages may be micropores (on the order of 0.1 to 1 nm) or mesopores (on the order of about 1 nm to about 90 nm). In some embodiments the nanocages produced according to methods herein may be configured for use in drug delivery, catalysis, energy storage or conversion, or chemical sensing due to their high surface area and unique properties.

The carbon nanocages may be produced with a carbon monoxide (CO) and Argon (Ar) plasma with a ratio of 1:9 CO:Ar, with Argon used as a swirl gas and CO provided as a core gas. In some embodiments the ratio may be at least 1:5, at least 1:8, at least 1:9, or at least 1:10 CO:Ar. The plasma apparatus may be provided with a power of about 24 kW, or at least about 10 KW, at least about 20 KW, at least about 24 KW to facilitate the creation of the carbon nanocages. The carbon nanocages may have about a 10-50 nm outer diameter with the shell thickness of about 2-5 nm, about a 20-50 nm outer diameter with a shell thickness of about 3-10 nm, or an outer diameter of about 50-100 nm with a the thickness of the graphitic shell thickness of about 5-15 nm or any range in between (i.e. about 10-20 nm outer diameter with a shell thickness of about 2-5 nm). The graphitic layers may have a spacing a spacing of about 0.35 nm. In some embodiments the nanocages may be configured such that the outer diameter is less than 100 nm.

In some embodiments additional solid carbon particles or catalyzing particles may be injected into the plasma plume in order to produce the carbon nanocages or to act as a template or substrate for the creation of solid carbon materials or carbon nanocages. For example, in some embodiments a ferrocene feedstock may be provided or injected into the plasma plume, such as discussed with regard to feedstock injection above. In some embodiments the ferrocene is subjected to pyrolysis in the plasma plume and recombines with CO in the plasma plume to produce carbon nanocages. In some embodiments the ferrocene particles may have a D50 of less than about 50 nm, less than about 40 nm, less than about 30 nm, less than 10 nm or any range in between.

### Additional Embodiments

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than restrictive sense.

Indeed, although this invention has been disclosed in the context of certain embodiments and examples, it will be understood by those skilled in the art that the invention extends beyond the specifically disclosed embodiments to other alternative embodiments and/or uses of the invention and obvious modifications and equivalents thereof. In addition, while several variations of the embodiments of the invention have been shown and described in detail, other modifications, which are within the scope of this invention, will be readily apparent to those of skill in the art based upon this disclosure. It is also contemplated that various combinations or sub-combinations of the specific features and aspects of the embodiments may be made and still fall within the scope of the invention. It should be understood that various features and aspects of the disclosed embodiments can be combined with, or substituted for, one another in order to form varying modes of the embodiments of the disclosed invention. Any methods disclosed herein need not be performed in the order recited. Thus, it is intended that the scope of the invention herein disclosed should not be limited by the particular embodiments described above.

It will be appreciated that the systems and methods of the disclosure each have several innovative aspects, no single one of which is solely responsible or required for the desirable attributes disclosed herein. The various features and processes described above may be used independently of one another or may be combined in various ways. All possible combinations and subcombinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination. No single feature or group of features is necessary or indispensable to each and every embodiment.

It will also be appreciated that conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the invention is not to be limited to the particular forms or methods disclosed, but, to the contrary, the invention is to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (e.g., as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (e.g., as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

What is claimed is:

1. A method for producing a solid carbon material using a microwave generated plasma, the method comprising:
propagating microwaves through a microwave plasma apparatus, the microwaves generated using a microwave generator;
injecting a plasma gas comprising carbon into the microwave plasma apparatus;
generating the microwave generated plasma by contacting the plasma gas with the microwaves, wherein contacting the plasma gas with the microwaves pyrolyzes the plasma gas to produce oxygen (O₂) gas and a carbon-containing gas; and
depositing the carbon-containing gas on a substrate to form the solid carbon material.

2. The method of claim 1, wherein the solid carbon material comprises an array of repeating carbon atoms.

3. The method of claim 1, wherein at least one portion of the substrate comprises a catalyzing transition metal.

4. The method of claim 1, wherein the solid carbon material comprises a crystalline carbon material.

5. The method of claim 4, wherein the crystalline carbon material comprises a carbon nanotube (CNT) or multi-walled carbon nanotube (MWCNT).

6. The method of claim 1, wherein the solid carbon material comprises a graphene sheet or carbon nanocages.

7. The method of claim 1, wherein at least one surface of the substrate comprises a catalyst.

8. The method of claim 7, wherein the catalyst facilitates growth of the solid carbon material in a repeating carbon structure comprising substantially pure carbon.

9. The method of claim 7, wherein the catalyst comprises particles having a diameter of about 1 nm to about 10 nm.

10. The method of claim 9, further comprising recycling the carbon-containing gas and injecting the recycled carbon-containing gas into the microwave plasma apparatus.

11. The method of claim 1, wherein the microwave plasma apparatus comprises one or more walls lined or coated with a material that prevents deposition of the solid carbon material on the one or more walls.

12. The method of claim 1, further comprising injecting an enabling gas into the microwave plasma apparatus while injecting the plasma gas into the microwave plasma apparatus.

13. A microwave plasma apparatus for generating a solid carbon material using a microwave generated plasma, the apparatus comprising:
a microwave waveguide for propagating microwaves generated using a microwave generator;
one or more gas ports for injecting a plasma gas, the one or more gas ports in communication with the microwave waveguide;
a reaction chamber with one or more chamber walls, the reaction chamber in communication with the microwave waveguide and the one or more gas ports, the reaction chamber comprising a heating region and a deposition region, and the one or more chamber walls comprising a lining or coating comprising a material that prevents crystal growth on the one or more chamber walls;
a substrate holder located in the deposition region of the reaction chamber, the substrate holder configured to house a substrate for depositing the solid carbon material thereon; and
a gas separator in communication with the reaction chamber, the gas separator configured to separate one or more gases generated in the heating region and/or the deposition region of the reaction chamber.

14. The apparatus of claim 13, wherein the substrate holder is substantially perpendicular to the one or more chamber walls.

15. The apparatus of claim 13, wherein the substrate holder is substantially parallel to the one or more chamber walls.

16. The apparatus of claim 13, wherein one or more portions of the substrate holder are removable and replaceable.

17. A method for producing carbon monoxide using a microwave generated plasma, the method comprising:
propagating microwaves through a microwave plasma apparatus, the microwaves generated using a microwave generator;
injecting a plasma gas comprising carbon into the microwave plasma apparatus;
generating the microwave generated plasma by contacting the plasma gas with the microwaves, wherein contacting the plasma gas with the microwaves pyrolyzes the plasma gas to produce carbon monoxide (CO) gas; and
removing the carbon monoxide gas from the microwave plasma apparatus.

18. The method of claim 17, wherein the removing the carbon monoxide gas from the microwave plasma apparatus comprises separating the carbon monoxide gas from other gaseous byproducts to purify the carbon monoxide gas.

19. The method of claim 17, wherein the plasma gas comprising carbon is carbon dioxide (CO₂).

20. The method of claim 17, additionally comprising depositing a solid carbon material on a substrate within the microwave plasma apparatus.
